(19) United States
(12) Patent Application Publication
(10) Pub. No.: US 2005/0116352 A1
(43) Pub. Date: Jun. 2, 2005

(54) Acoustic wave device and method of fabricating the same

(76) Inventors: Suguru Warashina, Kawasaki (JP); Takashi Matsuda, Kawasaki (JP); Masanori Ueda, Yokohama (JP); Osamu Kawachi, Yokohama (JP); Yasufumi Kaneda, Yokohama (JP)

Correspondence Address: ARENT FOX KINTNER PLOTKIN & KAHN, 1050 CONNECTICUT AVENUE, N.W., SUITE 400, WASHINGTON, DC, 20036, US

(21) Appl. No.: 10/986,448

(22) Filed: Nov. 12, 2004

(30) Foreign Application Priority Data
Nov. 14, 2003 (JP) 2003-385750
Jun. 24, 2004 (JP) 2004-186639

(51) Int. Cl. H01L 23/48

(52) U.S. Cl. 257/777

(57) ABSTRACT

An acoustic wave device includes a device substrate on which electrodes, first terminals, and a first metal seal layer located along an outer periphery are formed, a supporting substrate on which second terminals to be connected to the first terminals, and a second metal seal layer to be joined to the first metal seal layer are formed, and a conductive seal film provided on an outer surface of the device substrate, an outer surface of the first metal seal layer, and an outer surface of the second metal seal layer. The electrodes and the first and second terminals are hermetically sealed with the first and second metal seal layers and the seal film.

### BACKGROUND OF THE INVENTION

1. Field of the Invention

The present invention relates to an acoustic wave device and a method of fabricating the same, and more particularly, to an acoustic wave device having a chip size package and its fabrication method.

2. Description of the Related Art

Conventionally, the acoustic wave device is used in various fields. Recently, a filter with the acoustic wave device, particularly, a filter with a surface acoustic wave (SAW) chip has been of much interest. A demand for such SAW filters is rapidly increasing in the field of communication technology involving mobile communication devices such as portable telephones, because a SAW filter can restrict unnecessary signals in transmission and reception. Particularly, small-sized, highly reliable SAW filters are in great demand these days. A SAW filter that has comb-like electrodes formed on a piezoelectric substrate and is hermetically sealed is more preferable, because more stable characteristics can be obtained with such a SAW filter.

Japanese Patent Application Publication No. 2002-513234 discloses a packaging technique. By this technique, a piezoelectric substrate supported on a base plate is hermetically sealed. More specifically, sheets provided on the base plate are brought into contact with the side surfaces of the piezoelectric substrate, so that a hermetically sealed space is formed between the base plate and the piezoelectric substrate. Also, a frame is provided outside the sheets, and the piezoelectric substrate, the frame, and the sheets are covered with a metal plating material.

Japanese Patent Application Publication No. 2000-77970 discloses a packaging structure in which a seal ring is provided on each of a piezoelectric substrate and a supporting substrate, and the two substrates are bonded to each other by interposing a sealing material (such as solder) between the seal rings. With the sealing material being interposed between the seal rings of the two substrates, the space between the piezoelectric substrate and the supporting substrate is hermetically sealed. Also, a conductive covering film is employed to cover the outer surface of the sealing material. Further, a gold seal ring is provided for each of the piezoelectric substrate and the supporting substrate, and the gold seal rings are joined to each other so that the space between the piezoelectric substrate and the supporting substrate is hermetically sealed.

### SUMMARY OF THE INVENTION

It is therefore an object of the present invention to provide an acoustic wave device in which disadvantages with the above conventional structures are eliminated.

A more specific object of the present invention is to provide an acoustic wave device that is packaged in a chip size with high reliability and high performance, and a method of fabricating such an acoustic wave device.

The above objects of the present invention are achieved by an acoustic wave device comprising: a device substrate on which electrodes, first terminals, and a first metal seal layer located along an outer periphery are formed; a supporting substrate on which second terminals to be connected to the first terminals, and a second metal seal layer to be joined to the first metal seal layer are formed; and a conductive seal film provided on an outer surface of the device substrate, an outer surface of the first metal seal layer, and an outer surface of the second metal seal layer, the electrodes and the first and second terminals being hermetically sealed with the first and second metal seal layers and the seal film.

The above objects of the present invention are also achieved by an acoustic wave device comprising: a device substrate on which electrodes, first terminals, and a first metal seal layer located along an outer periphery are formed; and a supporting substrate on which second terminals to be connected to the first terminals, and a second metal seal layer to be joined to the first metal seal layer are formed, the electrodes and the first and second terminals being hermetically sealed with the first and second metal seal layers, the supporting substrate having grooves on its backside so as to form strips.

The above objects of the present invention are also achieved by an acoustic wave device comprising: a device substrate on which electrodes, first terminals, and a first metal seal layer located along an outer periphery are formed; and a supporting substrate on which second terminals to be connected to the first terminals, and a second metal seal layer to be joined to the first metal seal layer are formed, the electrodes and the first and second terminals being hermetically sealed with the first and second metal seal layers, the supporting substrate having materials buried therein, the materials being arranged so as to form stripes and having a linear expansion coefficient different from that of the supporting substrate.

### BRIEF DESCRIPTION OF THE DRAWINGS

Other objects, features and advantages of the present invention will become more apparent from the following detailed description when read in conjunction with the accompanying drawings, in which:

FIG. 1A is a sectional view of an acoustic wave device according to a first embodiment of the present invention;

FIG. 1B shows a circuit forming surface of a piezoelectric substrate;

FIG. 1C shows a circuit forming surface of a support substrate;

FIGS. 2A through 2H show a method of fabricating the acoustic wave device according to the first embodiment in which FIGS. 2A through 2C and 2D through 2F respectively show processes for producing the piezoelectric substrate and for producing the support substrate, followed by steps of FIGS. 2G and 2H;

FIG. 3 schematically shows a flattening a gold plating layer;

FIGS. 4A and 4B show a structure in which a terminal and a metal seal layer have an identical film structure in the acoustic wave device shown in FIGS. 1A through 1C;

FIGS. 5A and 5B show a structure in which a silicon oxide film, which is a poor wettability to solder, is provided on the top of a metal interconnection in order to prevent invading of solder to an IDT;

FIG. 6A shows an arrangement of a silicon oxide film provided on a piezoelectric substrate employed in a third embodiment;

FIG. 6B shows another arrangement without the silicon oxide film;

FIGS. 7A and 7B show an arrangement in which an interconnection layer is partially covered with a Ti layer in order to prevent invading of solder;

FIG. 8 shows a piezoelectric substrate used in a fifth embodiment of the present invention;

FIGS. 9A, 9B and 9C show a structure in which members of glass having a comparatively small linear expansion coefficient are bonded to the supporting substrate in the form of lines;

FIGS. 10A, 10B and 10C show a structure in which a substance (such as groove or gap) having a linear expansion coefficient different from that of a support substrate is provided on or in the supporting substrate in the form of lines;

FIG. 11 illustrates an acoustic wave device in accordance with a seventh embodiment of the present invention;

FIGS. 12A and 12B illustrate an acoustic wave device in accordance with an eighth embodiment of the present invention;

FIG. 13 illustrates an acoustic wave device in accordance with a ninth embodiment of the present invention;

FIG. 14 illustrates an acoustic wave device in accordance with a tenth embodiment of the present invention;

FIG. 15 shows a process for inserting a seal member into a hole formed in a supporting substrate from the circuit forming surface thereof;

FIGS. 16A through 16C illustrate an acoustic wave device in accordance with an eleventh embodiment of the present invention;

FIGS. 17A through 17C illustrate an acoustic wave device in accordance with a twelfth embodiment of the present invention;

FIGS. 18A, 18B and 18C show an acoustic wave device in accordance with a thirteenth embodiment of the present invention;

FIGS. 19A, 19B and 19C show an acoustic wave device in accordance with a fourteenth embodiment of the present invention; and

FIGS. 20A, 20B and 20C show an acoustic wave device in accordance with a fifteenth embodiment of the present invention.

### DESCRIPTION OF THE PREFERRED EMBODIMENTS

The following is a description of embodiments of the present invention, with reference to the accompanying drawings.

### First Embodiment

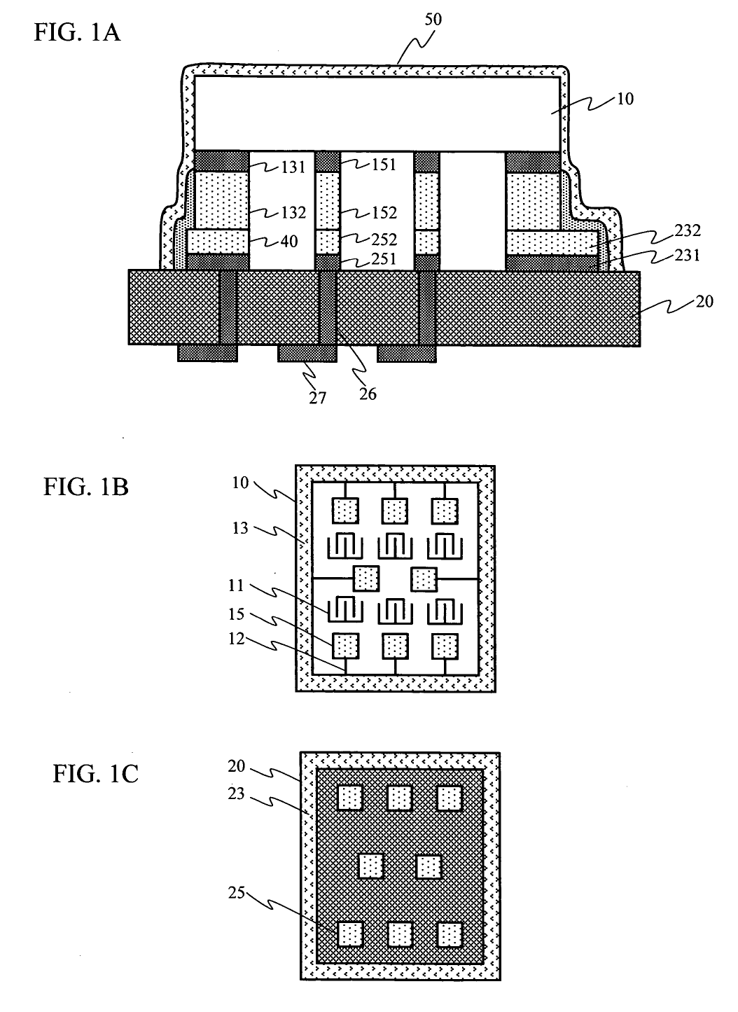

FIGS. 1A through 1C illustrate an acoustic wave device in accordance with a first embodiment of the present invention. FIG. 1A is a section view of the acoustic wave device. FIG. 1B shows the circuit forming surface of a piezoelectric substrate 10. FIG. 1C shows the circuit forming surface of a supporting substrate 20.

This acoustic wave device includes the piezoelectric substrate 10 and the supporting substrate 20. The piezoelectric substrate 10, which is also referred to as device substrate, may be made of LiTaO₃ (hereinafter simply referred to LT) or LiNbO₃ (hereinafter simply referred to LN). Preferably, the piezoelectric substrate 10 has a resistivity equal to 10¹⁴-10¹⁷ Ωm in order to cope with pyroelectricity. The supporting substrate 20 may be a ceramic substrate, silicon substrate, glass substrate or gallium arsenide (GaAs) substrate.

The chip-type piezoelectric substrate 10 is facedown bonded to the supporting substrate 20. As shown in FIG. 1B, comb-like electrodes 11, terminals 15, a metal layer 13 for sealing, and high-resistance patterns 12 are formed on the circuit forming surface of the piezoelectric substrate 10. The comb-like electrodes 11 are connected in a ladder-like fashion, for example, via wires (now shown). For simplification of the drawing, the comb-like electrodes 11 shown in FIG. 1B are not shown in FIG. 1A. The terminals 15 that function as ladder-type input-output terminals or ground terminals are formed in the vicinities of the comb-like electrodes 11. Each of the terminals 15 is connected to the metal seal layer 13 via the high-resistance patterns 12. The metal seal layer 13 is a ring-like metal layer that is uniformly formed along the outer periphery of the circuit forming surface. Hereinafter, the metal seal layer 13 is also referred to as a seal ring. The metal seal layer 13 is formed to surround the comb-like electrodes 11 and the terminals 15.

As shown in FIG. 1C, a metal layer 23 and terminals 25 are formed on the circuit forming surface of the supporting substrate 20. As the piezoelectric substrate 10 is facedown bonded to the supporting substrate 20, the metal seal layer 13 of the piezoelectric substrate 10 is joined to the metal layer 23 of the supporting substrate 20, and the terminals 15 are respectively joined to the terminals 25. The metal layer 23 is a ring-like metal layer that is uniformly formed along the outer periphery of the circuit forming surface. Hereinafter, the metal layer 23 is also referred to as a seal ring. In the structure shown in FIGS. 1A through 1C, the metal layer 23 is slightly wider than the metal seal layer 13, and a step-like portion is formed outside. The supporting substrate 20 has through holes (through wires) 26 that communicate with the terminals 25 and are connected to external-connection pads 27 formed on the bottom surface. With the terminals 15 being first terminals, the terminals 25 are considered to be second terminals. With the metal seal layer 13 being a first metal layer, the metal layer 23 is considered to be a second metal layer.

The metal layer 23 includes an adhesion layer 231 that is formed on the circuit forming surface of the supporting substrate 20, and a gold plating layer 232 that is formed on the adhesion layer 231. The adhesion layer 231 should preferably be used to increase the adhesion of the gold plating layer 232 to the piezoelectric substrate 10. Likewise, each of the terminals 25 includes an adhesion layer 251 that is formed on the circuit forming surface of the supporting substrate 20, and a gold plating layer 252 that is formed on the adhesion layer 251. The gold plating layers 232 and 252 are grown on the adhesion layers 231 and 251, respectively. In a case where the supporting substrate 20 is made of ceramics, the adhesion layers 231 and 251 each have a double-layer structure of tungsten (W) and nickel (Ni), for example.

The metal layer 13 of the piezoelectric substrate 10 to be joined to the metal layer 23 includes an adhesion layer 131 and a gold plating layer 132 formed on the adhesion layer 131. Each of the terminals 15 also includes an adhesion layer 151 and a gold plating layer 152 formed on the adhesion layer 151. In a case where the piezoelectric substrate 10 is made of LT (LiTaO₃), the adhesion layers 131 and 151 each have a double-layer structure that includes a titanium (Ti) film as a base and a gold layer formed on the titanium film, for example.

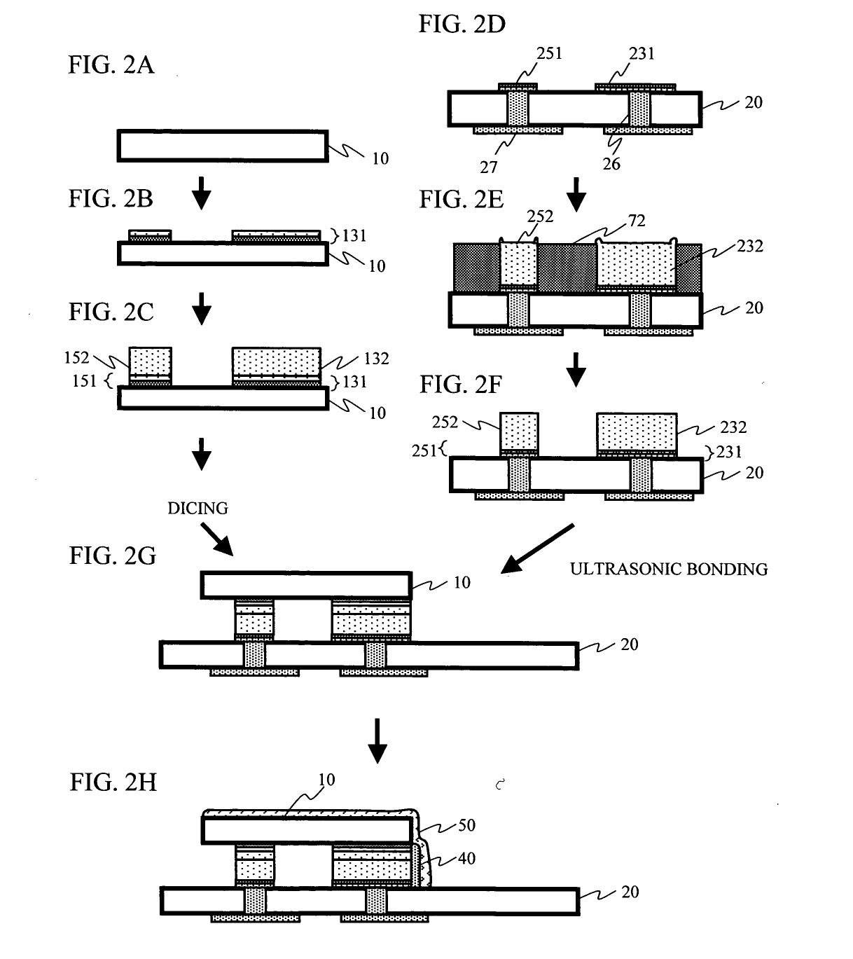

FIGS. 2A through 2H illustrate a method of producing an acoustic wave device in accordance with the first embodiment. FIGS. 2A through 2C show the process for producing the piezoelectric substrate 10, and FIGS. 2D through 2F show the process for producing the supporting substrate 20. The process for producing the piezoelectric substrate 10 is first described in detail. The comb-like electrodes 11 are formed on the circuit forming surface of a LT wafer 10A (step A). A resist is then applied onto the circuit forming surface of the LT wafer 10A with a spin coater. After sputtering, a Ti film is formed by a sputtering technique or a vapor deposition technique, and an Au film is formed by a sputtering technique. Thus, adhesion layers 131 and 151 each having a thickness of approximately 300 nm are formed (step B). Next, a gold plating layer 132 and a gold stud bump 152 are respectively formed on the adhesion layers 131 and 151 (step C). The gold stud bump 152 may be a gold plating layer.

A process for producing the supporting substrate 20 is as follows. In step D, the through holes 26, the terminals 27, and the adhesion layers 231 and 251 each having a double-layer structure of W and Ti are formed on the supporting substrate 20. When the adhesion layers 231 and 251 are composed of two layers of W and Ti, the W film may be approximately 10 μm thick and the Ti film may be 2 to 6 μm thick. By a printing technique, the terminals (pads) 27 are formed on the bottom surface of the supporting substrate 20. A resist 72 is then applied, and the adhesion layers 231 and 251 are formed by growing gold films of 20 to 25 μm in thickness through a plating process (step E). After the gold plating layer is flattened, the resist 72 is removed so as to form the gold plating layers 232 and 252.

Since the gold plating layers 232 and 252 are thick as much as 20 μm, there may be some difficulty in evenly coating the resist by the normal spin coater, if there is a large step on the surface. In such a case, the spray coater may be substituted for the spin coater in order to realize coating of the uniform resist. A dry film may also be substituted for the spray coater.

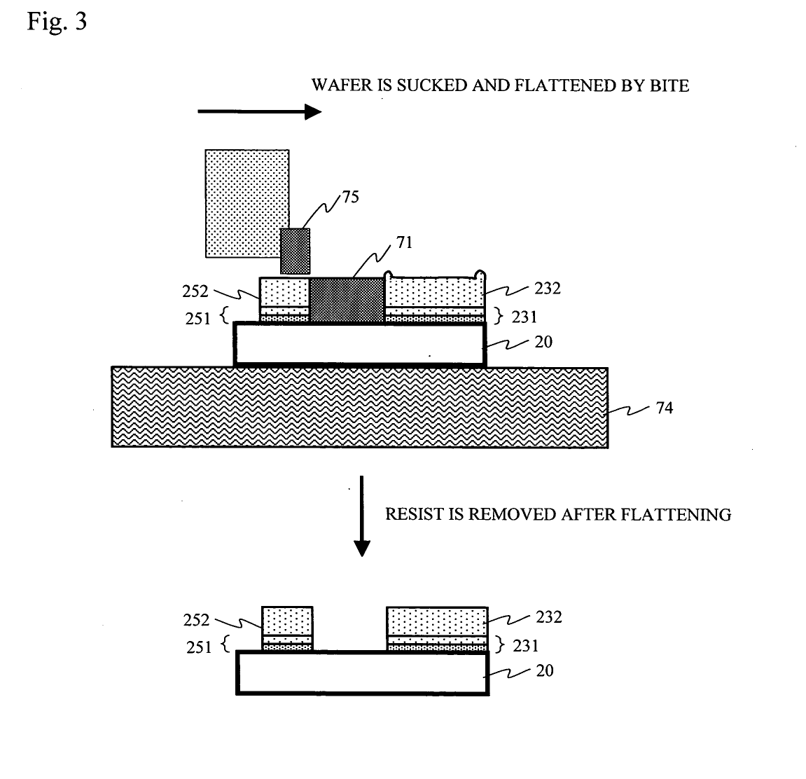

FIG. 3 schematically illustrates the process for flattening the gold plating layers 232 and 252. The wafer 10A is sucked and attached to a substrate supporting base 74 of a lathe. The supporting substrate 20 is then flattened with a cutting tool (bite) 75 with reference to the backside of the supporting substrate 20. After the flattening, the resist 71 is removed. Instead of the resist 71, an insulating film such as a silicon oxide film may be used. The flattening process results in the flat joining surfaces and improves hermetical sealing. The flattening process may be applied to flattening of the gold plating layer 132 and the gold stud bump 153 in step E.

Then, as shown in step G of FIG. 2, the gold plating layer 132 and the gold plating layer 232 are joined to each other by ultrasonic bonding, so that the space between the circuit forming surface of the piezoelectric substrate 10 and the circuit forming surface of the supporting substrate 20 can be hermitically sealed. In case where oxygen is contained during the joining process, the metal may be oxidized, so that hermetical sealing may be degraded. In order to avoid this problem, it is preferable to fill the sealed space with inactive gas such as argon or nitride gas or to carry out the joining process under a depressurized condition.

When the gold plating layers 132 and 232 are joined to each other, the gold plating layers 152 and 252 are joined to each other at the same time. By doing so, electric connection is established between the circuit formed on the piezoelectric substrate 10 and the terminals 27 of the supporting substrate 20. A seal film 50, which may be made of an electrically conductive material such as a metal, is provided on the supporting substrate 20 so as to cover the outer surface of the piezoelectric substrate 10 and the outside of the metal seal layer 13.

For example, the seal film 50 has a double-layer structure composed of a Ti film and a copper film. Ti is deposited to a thickness of 100 nm by sputtering or evaporation, and Cu is grown to a thickness of 3 μm by electrolytic plating. Sputtering of Ti may be replaced by electroless Ni plating. Besides the double-layer structure, a film that contains copper, gold or indium may be used. The seal film 50 may be made of electrically conductive resin.

### Second Embodiment

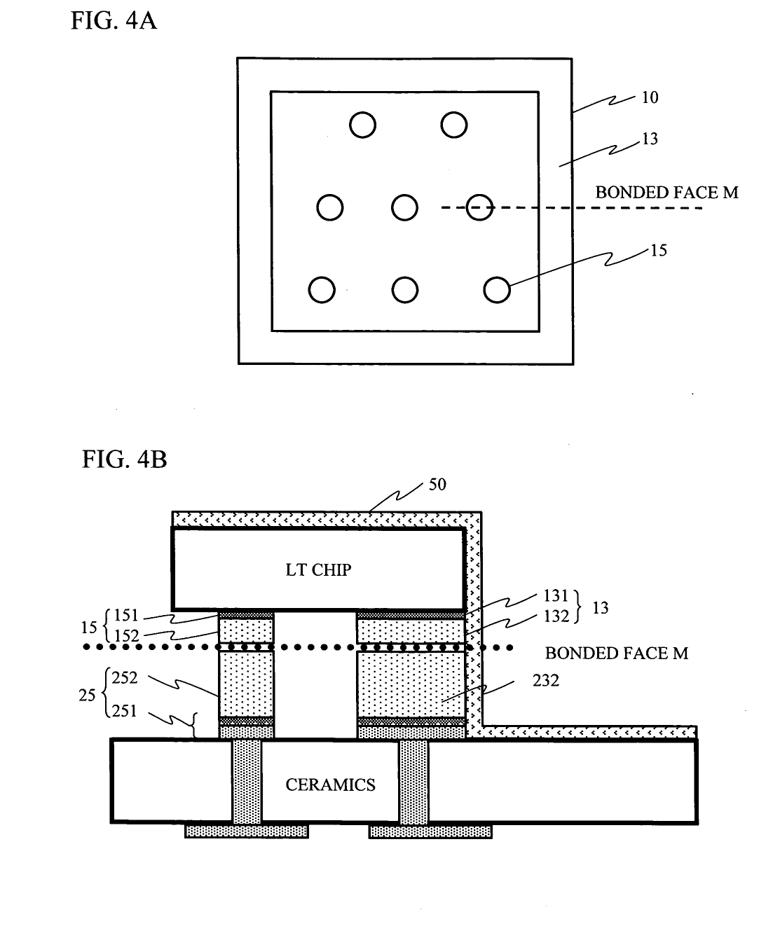

FIGS. 4A and 4B show a structure in which the terminal and the metal seal layer have an identical film structure in the device of FIGS. 1A through 1C. In these figures, the same reference numerals as those used in the previous description refer to the same elements. More particularly, FIG. 4A shows the circuit forming surface of the piezoelectric substrate 10, and FIG. 4B schematically shows the cross section taken along a line M shown in FIG. 4A. In contrast to the first embodiment shown in FIGS. 1A through 1C that employs the gold stud bump 152 between the first and second terminals, the second embodiment employs layers 232 and 252 that contain gold and tin, while the metal seal layer 13 includes gold and tin. The metal seal layer 13 may be a layer made of a silver-tin alloy, a tin-antimony alloy, a gold-tin alloy, a gold-silicon alloy, a gold-germanium alloy, a tin-lead alloy.

### Third Embodiment

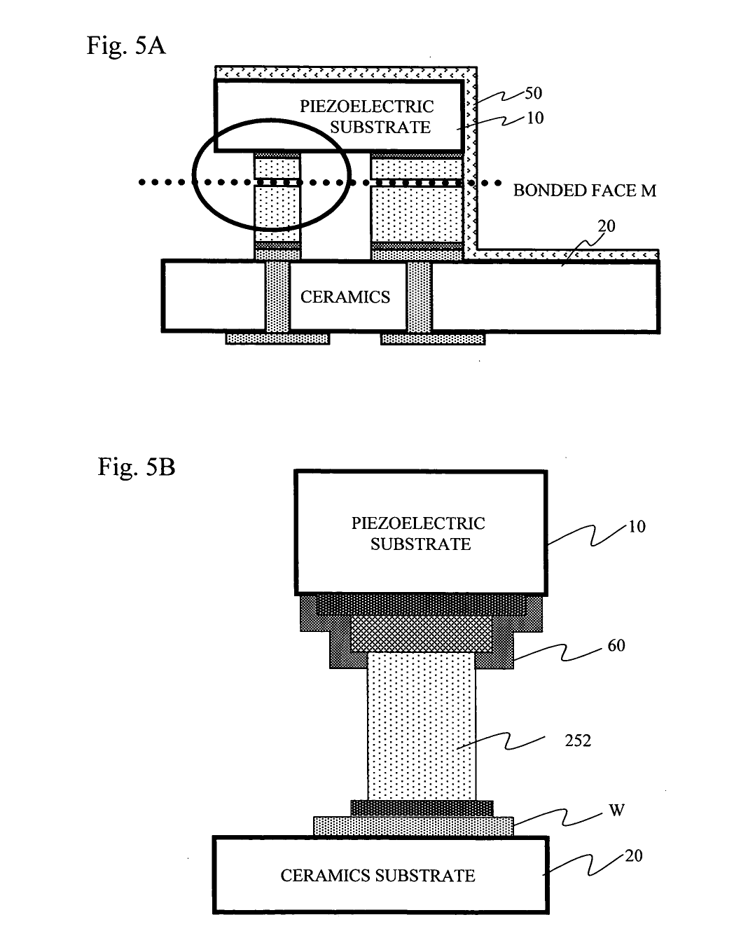

FIGS. 5A and 5B show a modification of the structure shown in FIGS. 4A and 4B in which a silicon oxide film, which is a poor wettability to solder, is provided on the top of a metal interconnection layer in order to prevent invading of solder to comb-like electrodes. The same reference numerals as those used in the previously described description refer to the same elements. More particularly, FIG. 5A is a cross-sectional view of an acoustic wave device according to this embodiment of the invention, and FIG. 5B is an enlarged view of joining of the piezoelectric substrate 10 and the supporting substrate 20 via the gold-tin layer 252. In case solder is used as a seal member, solder that is melted at a high temperature may invade the IDTs formed on the piezoelectric substrate 10. This problem can be avoided by growing a silicon oxide film 60 having a thickness of, for example, 100 nm, on a part of the metal interconnection layer on the piezoelectric substrate 10. It is to be noted that the silicon oxide film has a poor wettability to solder.

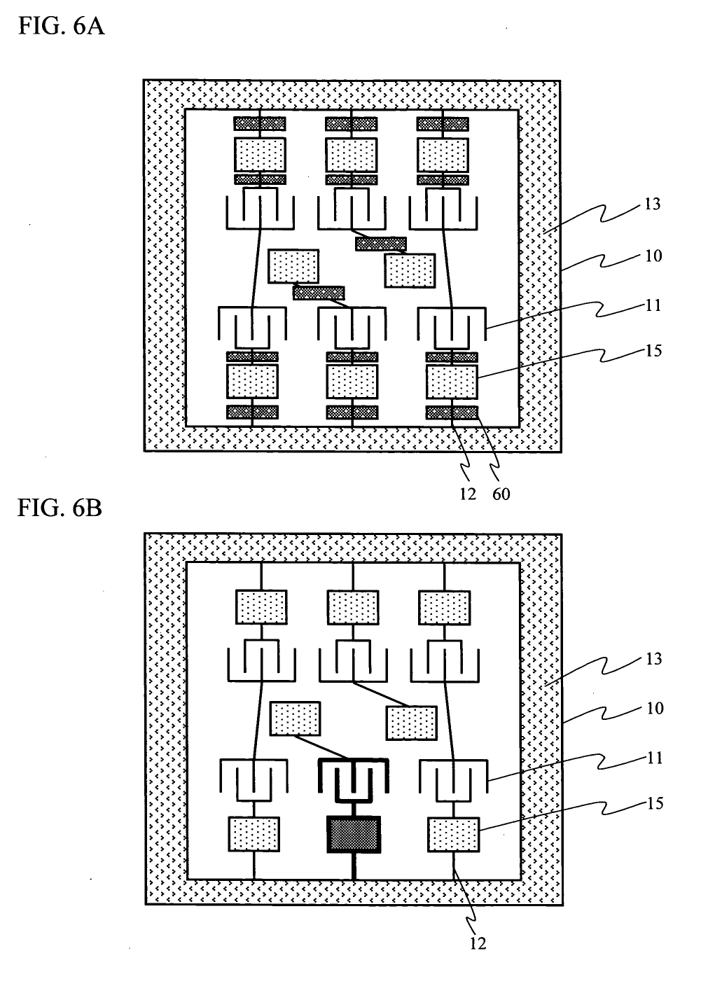

FIG. 6A shows the silicon oxide film 60 partially provided on the piezoelectric substrate 10, and FIG. 6B shows a comparative example in which the silicon oxide film 60 is not provided at all. As is shown in FIG. 6A, the high-resistance patterns 12 of metal lines are provided between the IDTs 11 and the terminals 15. The silicon oxide films 60 having a poor wettability to solder are provided so as to cover parts of the gold interconnection lines. In the absence of the silicon oxide films 60, solder that is maintained at a high temperature may be melted and invade the high-resistance patterns 12, the terminals 15 and the comb-like electrodes 11, and may cause a faulty performance. In contrast, the silicon oxide films 60 provided as shown in FIG. 6A prevent invading of solder and the resultant faulty performance. Silicon nitride films may be substituted for the silicon oxide films 60.

### Fourth Embodiment

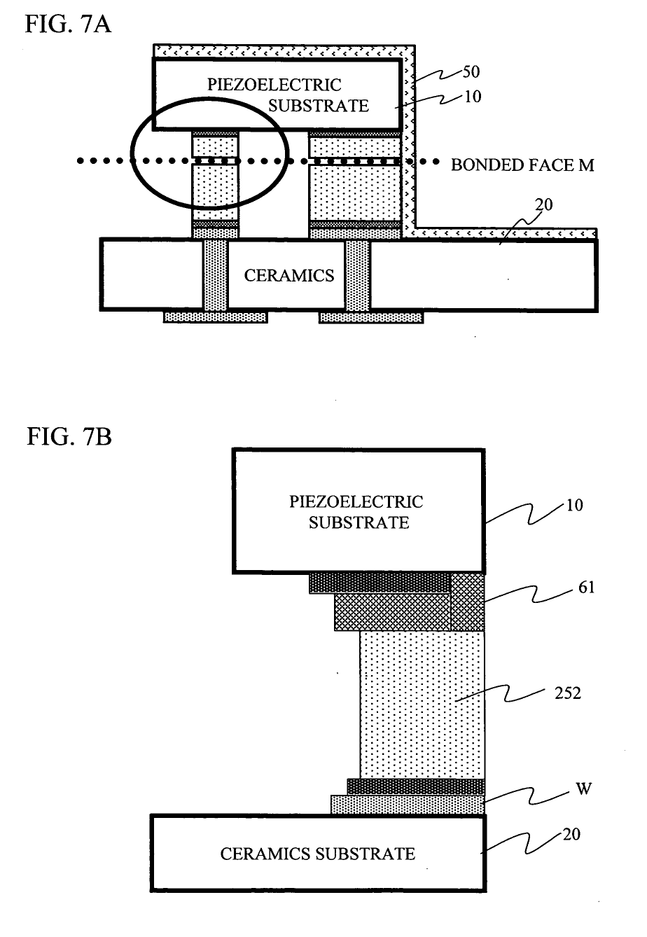

FIGS. 7A and 7B show another arrangement directed to preventing solder from invading the IDTs in which the silicon oxide films used in the third embodiment are replaced by a titanium film that covers a part of the interconnection layer. In FIGS. 7A and 7B, the same reference numerals as those used in the previous description refer to the same elements. More particularly, FIG. 7A is a cross-sectional view of an acoustic wave device according to this embodiment, and FIG. 7B is an enlarged view of joining of the piezoelectric substrate 10 and the supporting substrate 20 via the gold-tin layer. In case solder is used as a seal member, solder that is melted at a high temperature may invade the IDTs formed on the piezoelectric substrate 10. This problem can be avoided by providing the Ti film 61 on a part of the gold interconnection line on the on the piezoelectric substrate 10. The Ti film 61 prevents invading of solder.

### Fifth Embodiment

The present invention has an arrangement in which stripes are formed by the metal seal layer 13 on the piezoelectric substrate 10 on which the silicon oxide films 60 are also provided as shown in FIG. 6A.

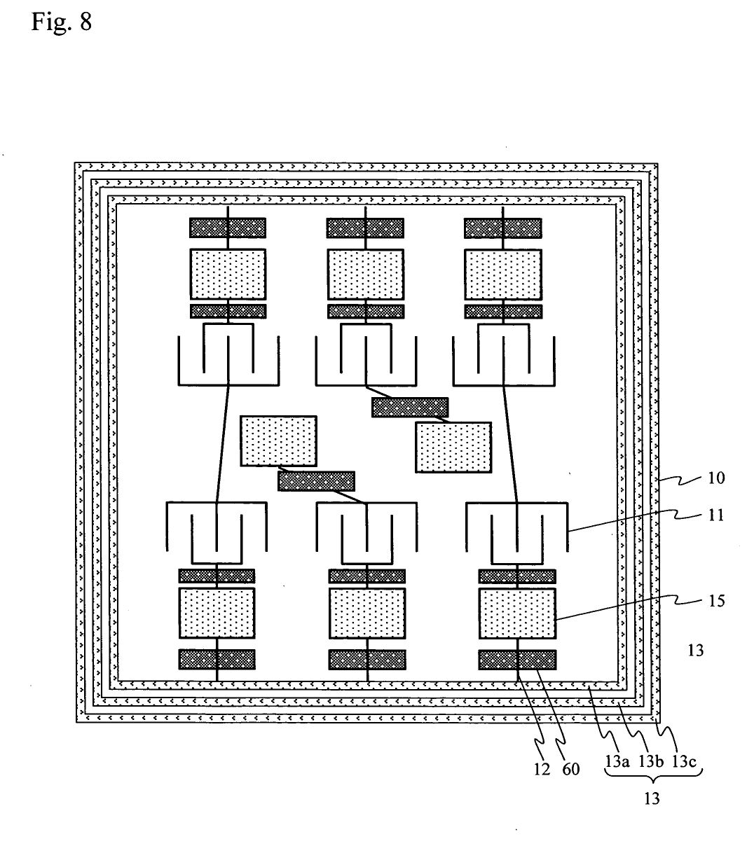

FIG. 8 shows the piezoelectric substrate 10 employed in the present embodiment. The metal seal layer 13 is composed of three belt layers 13a, 13b and 13c. This reduces the seal area (contact area) and raises the pressure applied to the piezoelectric substrate 10 at the time of joining, so that the ability of sealing can be improved.

The comb-like electrodes 11 and the terminals 15 are connected by the high-resistance patterns 12 of gold interconnection lines formed on the piezoelectric substrate 10 employed in this embodiment the high-resistance patterns 12 are partially covered with the silicon oxide films 60 that have a poor wettability to solder. This makes it possible to prevent invading of melted solder and avoid the occurrence of faulty devices.

The belt layers 13a-13c of the metal seal layer 13 may be made of solders having different compositions. For instance, solder having a composition of gold by 80 wt % and tin by 20 wt % has a melting point as high as 280° C., while it is expensive due to the use of gold. In contrast, solder having a composition of tin 96.5 wt % and silver by 3.5 wt % has a melting point as low as 221° C., while it is less expensive. With the above in mind, the metal seal layer 13 is formed by the combination of solders having different compositions. For example, the belt layers 13a and 13c are made of solder containing tin by 96.5 wt % and silver by 3.5 wt %, while the belt layer 13b is made of solder containing gold by 80 wt % and tin by 20 wt %. The suitable combination of solders having different compositions contributes to reducing the cost of producing the metal seal layer 13. The above-mentioned exemplary combination meets a 260° C. reflow test that is a reliability test of lead-free solder because it the metal seal layer 13 includes solder of gold by 80 wt % and tin by 20 wt %, these metals having high melting points. The metal seal layer 13 may be joined with solder composed of tin by 96.5 wt % and silver by 3.5 wt %. After joining, the chip is covered by a ring-shaped alloy foil composed of gold by 80 wt % and tin by 20 wt %, and is annealed at 300° C. This process improves the reliability of the device in reflow.

### Sixth Embodiment

In joining of the metal seal layer 13, solder is heated at a temperature higher than the melting point. For example, alloy solder of gold by 80 wt % and tin by 20 wt % has a melting point of 280° C., and is heated at approximately 300° C. in the joining process. When the device is cooled to the room temperature after joining, residual stress occurs in the joining portion due to the difference in linear thermal expansion coefficient between the supporting substrate 20 made of ceramics and the piezoelectric substrate 10 of LT. The residual stress may degrade the reliability of the device. It is conceivable to use, as the supporting substrate 10, an organic substrate having a linear expansion coefficient close to that of ceramics in order to avoid the above-mentioned problem. The organic substrate may be made of glass epoxy. However, it should be noted that the piezoelectric substrate 10 has anisotropy in the linear expansion coefficient (unit: x 10⁻⁶/° C.).

TABLE 1

| Inorganic | Organic | Piezoelectric | |
|---|---|---|---|
| substrate | substrate | substrate | Metal |
| alumina: 6-7.7 | glass epoxy: 10- | LT: x = 8, | Sn 96.5 wt % & Ag |
| | 15 | Y = 16 | 3.5 wt %: 22.2 |
| mullite: 2-4 | BT resin: 13-17 | LN: X = 8, | Au 80 wt %, & Sn |
| | | Y = 15 | 20 wt %: 16.2 |
| glass: 2-4 | Teflon: 10 | | Sn 63 wt % & Pb |
| | | | 37 wt %: 21 |
| silicon: 2.5 | | | gold: 14.2 |
| sapphire: 4.5- | | | Sn: 19.9 |
| 5.3 | | | |

In order to restrain occurrence of stress due to the difference in the linear expansion coefficient, the organic substrate is processed so as to have grooves or have line-shaped members made of a material (for example, glass or mullite) having a small linear expansion coefficient joined on the surface in order to match the whole linear expansion coefficient of the supporting substrate with that of the piezoelectric substrate. A metal (for example, gold) having a Vickers hardness equal to or less than 100 may be used to relax stress due to the difference in the linear expansion coefficient.

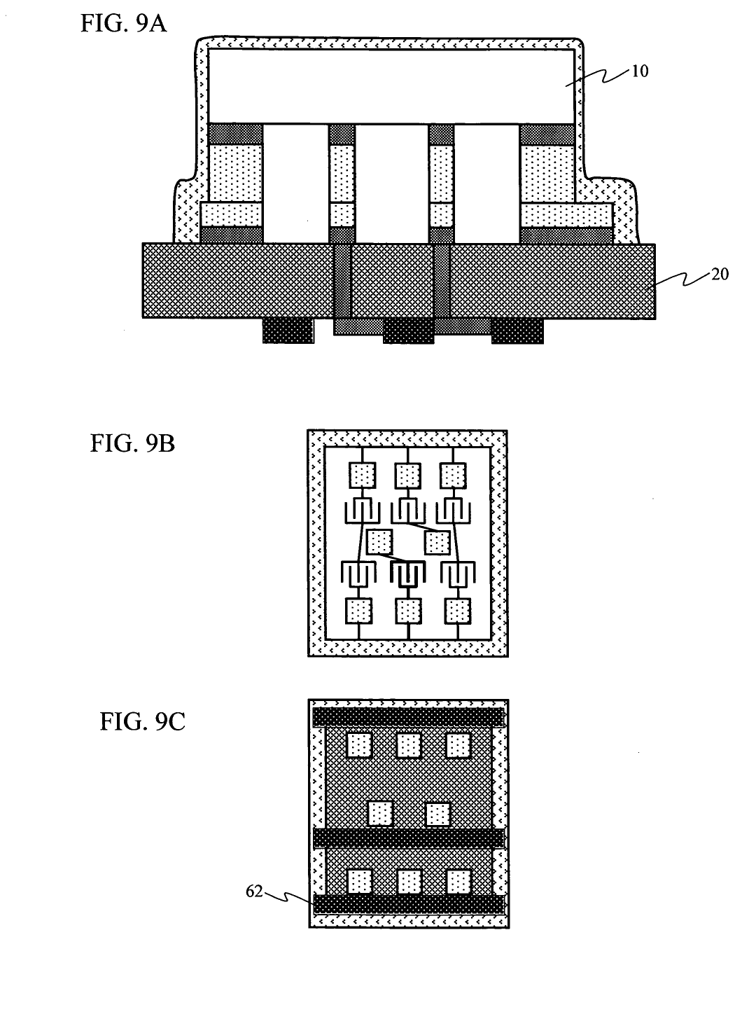

FIGS. 9A, 9B and 9C show a structure in which members 62 of glass having a comparatively small linear expansion coefficient are bonded to the supporting substrate 20 in the form of lines. The glass members 62 shaped into lines are bonded to the backside of the supporting substrate 20, so that the whole linear expansion coefficient of the supporting substrate 20 can be matched with that of the piezoelectric substrate 10.

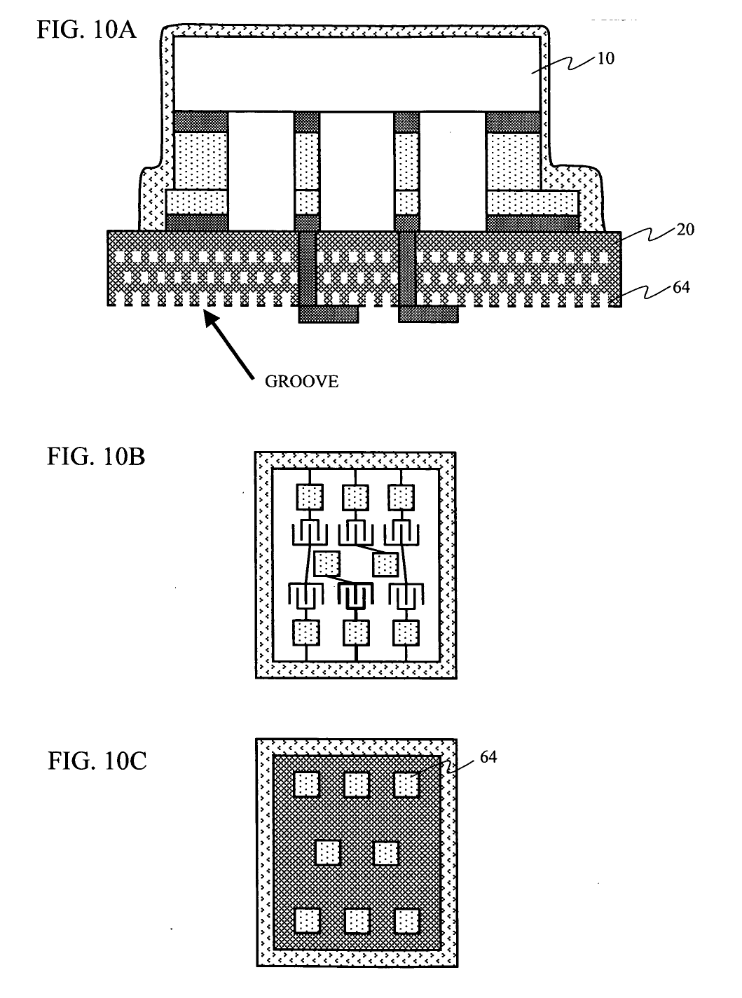

As shown in FIGS. 10A, 10B and 10C, a substance 64 (groove or gap) may be provided on or in the supporting substrate 20, wherein the substance 64 has a linear expansion coefficient different from that of the supporting substrate 20.

The adhesion layers 131 and 231 of tin-based solder may use Ti, Ni or Cu, these metals having good wettability. When Ni is used as the underlying metal provided on the LT substrate, the Ni film does not have good adhesiveness to the LT substrate. However, this problem can be solved by using a laminate of LT substrate/silicon oxide film/Ti/Ni/metal thin film. This laminate prevents removal of films due to stress. It is also possible to contain Co in the Ni film to thus improve resistance to reflow (see, for example, Japanese Patent No. 2750232). A titanium-tungsten alloy may be used.

### Seventh Embodiment

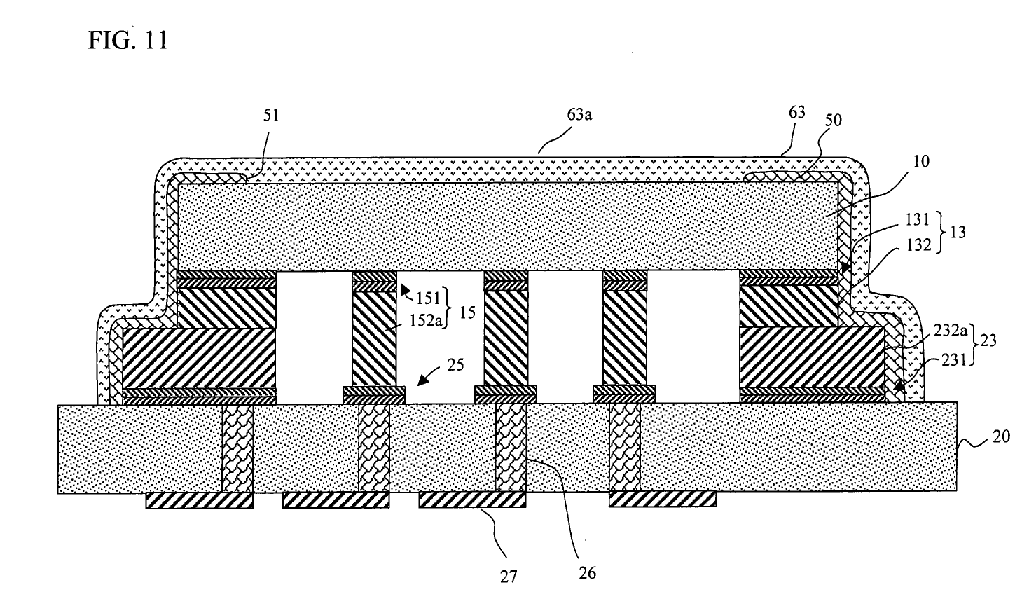

FIG. 11 is a cross-sectional view of an acoustic wave device according to a seventh embodiment of the present invention. The metal seal film 50 does not have any portions that face the comb-like electrodes 11. That is, the metal seal film 50 is not provided on specific backside regions of the piezoelectric substrate 10 opposite to a surface region thereof on which the comb-like electrodes 11 are formed. In the cross section of FIG. 11, the metal seal film 50 is not provided inside the seal ring composed of the metal seal layers 13 and 23. That is, the seal film 50 has a window 51 so as to surround the comb-like electrodes 11. The window 51 is filled with a coating material (film) 63. The portion of the coating material 63 filling the window 51 is denoted by reference numeral 63a. Since the comb-like electrodes 11 do not face the metal seal film 50 in this structure, the parasitic capacitance in this structure can be reduced. The window 51 of the seal film 50 is formed by applying a resist onto the bottom surface of the piezoelectric substrate 10, forming a Ti film by a sputtering technique or a vapor deposition technique, and then plating the Ti film with Cu. Parylene or BCB is then applied so as to form the coating material 63 to fill the window 51.

### Eighth Embodiment

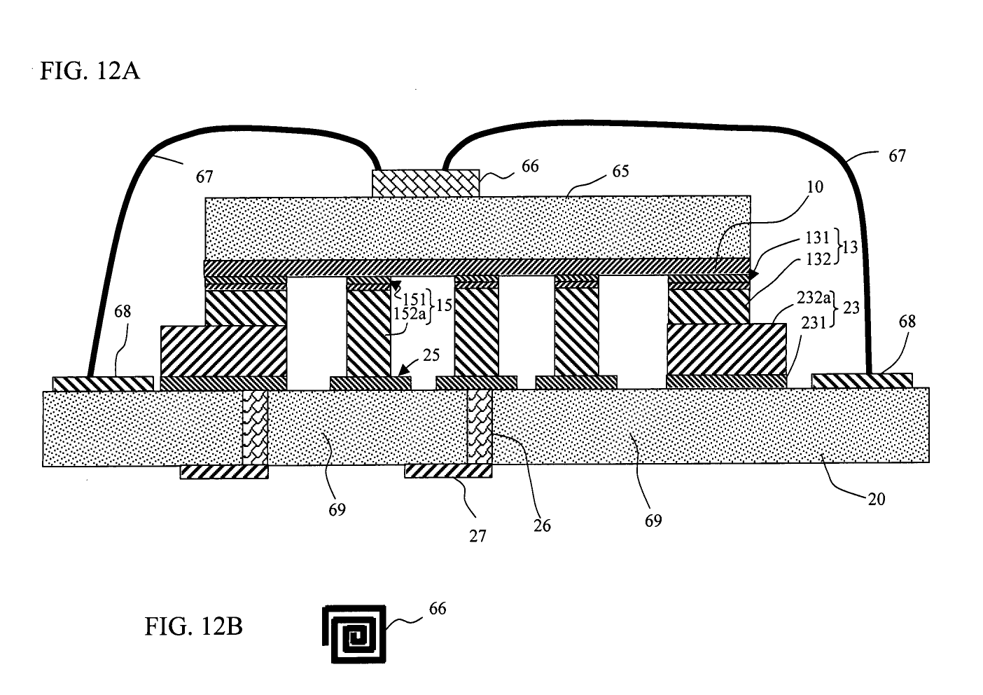

FIG. 12A is a section view of an acoustic wave device in accordance with a eighth embodiment of the present invention. In FIG. 12A, the same components as those of the foregoing embodiments are denoted by the same reference numerals as the corresponding ones of the foregoing embodiments. As shown in FIG. 12A, a supporting substrate 65 that is made of a different material from the piezoelectric substrate 10 is provided on the bottom surface of the piezoelectric substrate 10. The supporting substrate 65 is a second supporting substrate while the supporting substrate 20 is a first supporting substrate. The supporting substrate 65 is made of sapphire. Alternatively, the supporting substrate 65 may be made of glass, diamond, or high-resistance silicon. By joining the supporting substrate 65 made of such a material to the piezoelectric substrate 10, the temperature characteristics of the filter can be improved. More specifically, even when there is a temperature variation, variations in the center frequency and the band width of the pass band can be restricted. This effect is emphasized in a case where sapphire is employed. To join the piezoelectric substrate 10 and the supporting substrate 65 to each other, surface activation treatment using argon can be performed. The surface activation treatment can be performed at a normal temperature.

On the piezoelectric substrate 10, provided are a transmit filter formed by an acoustic wave element, a receive filter formed by another acoustic wave element and reactance elements such as inductors and capacitors. An inductor 66 is formed on the bottom surface of the supporting substrate 65. The inductor 66 is used for matching impedance with the outside, for example. The inductor 66 may have a spiral pattern shown in FIG. 12B. The inductor 66 may be formed by growing a 10 μm thick copper film by a plating technique, for example. The inductor 66 is electrically connected to pads 68 with bonding wires 67.

The pads 68 are formed on the circuit forming surface of the supporting substrate 20. The pads 68 are connected to the terminals 25 via interlayer wiring patterns 69 formed in the supporting substrate 20 that is a multi-layer ceramics substrate. The terminals 25 are connected to the comb-like electrodes 11 via the terminals 15 of the piezoelectric substrate 10 including the gold stud bumps 152a. With this wiring structure, the inductor 66 can be electrically connected to the comb-like electrodes 11. In FIG. 12B, the seal ring is formed with the gold plating layer 132 and the sealing material layer 232a made of solder or the like, and the piezoelectric substrate 10 and the supporting substrate 20 are connected to each other with the gold stud bumps 152a. These aspects are also seen in the structure of the first and second embodiments. Since the seal ring is formed with the gold plating layer 132 and the sealing material layer 232a, the metal seal film 50 and the coating film 60 can be omitted.

The second supporting substrate 65 having the inductor 66 formed on its bottom surface may also be applied to the first embodiment. However, if the seal film 50 and the coating film 63 are not employed, it is preferable to form the seal ring with the gold plating layer 132 and the sealing material layer 232a.

Instead of the inductor 66, a passive element such as a capacitor or a resistance may be formed on the bottom surface or a surface of the second supporting substrate 65.

### Ninth Embodiment

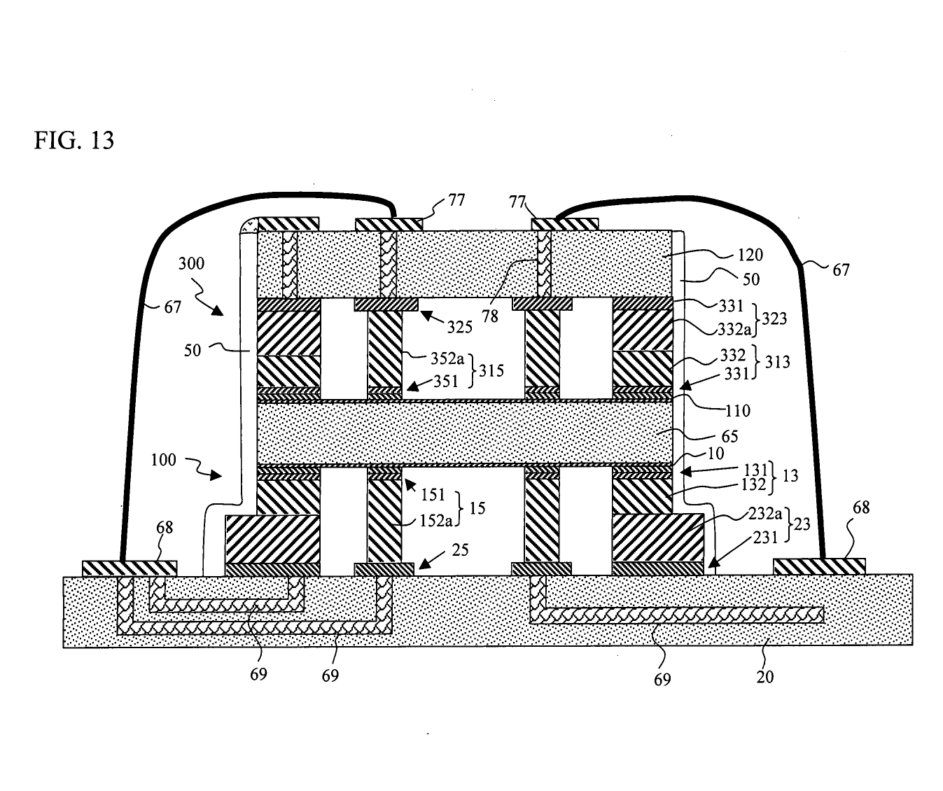

FIG. 13 is a section view of an acoustic wave device in accordance with a ninth embodiment of the present invention. In FIG. 13, the same components as those of the foregoing embodiments are denoted by the same reference numerals as the corresponding ones of the foregoing embodiments. The acoustic wave device in accordance with the seventh embodiment has two acoustic wave devices 100 and 300 combined in the vertical direction. The acoustic wave device 100 has the same structure as the structure shown in FIG. 12A (except for the inductor 66). The acoustic wave device 300 has the same structure as the acoustic wave device 100. More specifically, the acoustic wave device 300 includes a LT piezoelectric substrate 110 that is formed on a supporting substrate 65 made of sapphire, and a supporting substrate 120 that is made of ceramics.

A metal layer (seal ring) 313 that is formed with an adhesion layer 331 and a gold plating layer 332, pads 351, and gold stud bumps 352a formed on the pads 351 are formed on the circuit forming surface of the piezoelectric substrate 110. A metal layer (seal ring) 323 formed with an adhesion layer 331 and a sealing material layer 332a formed on the adhesion layer 331, pad-like terminals 325, comb-like electrodes (not shown), and high-resistance patterns shown in FIG. 1B, are formed on the circuit forming surface of the supporting substrate 120.

The piezoelectric substrate 110 is facedown bonded to the supporting substrate 120. As the gold plating layer 332 is bonded to the sealing material layer 332a, a hermetically sealed space is formed inside. Through holes 78 are formed in the supporting substrate 120. Also, pads 77 that are to be connected to the through holes 78 are formed on the surface opposite from the circuit forming surface of the supporting substrate 120 (the upper surface of the supporting substrate 120). The pads 77 are electrically connected to the pads 68 of the supporting substrate 20 with the bonding wires 67. With this wiring structure, the two devices 100 and 300 are electrically connected to each other. If the devices 100 and 300 each have a two-stage ladder structure, for example, the devices 100 and 300 are connected in series to produce a four-stage ladder filter. The outer surfaces of the devices 100 and 300 are covered with the seal film 50.

In this structure, a acoustic wave device is formed on either side of the sapphire supporting substrate 65. Thus, the chip area can be reduced.

### Tenth Embodiment

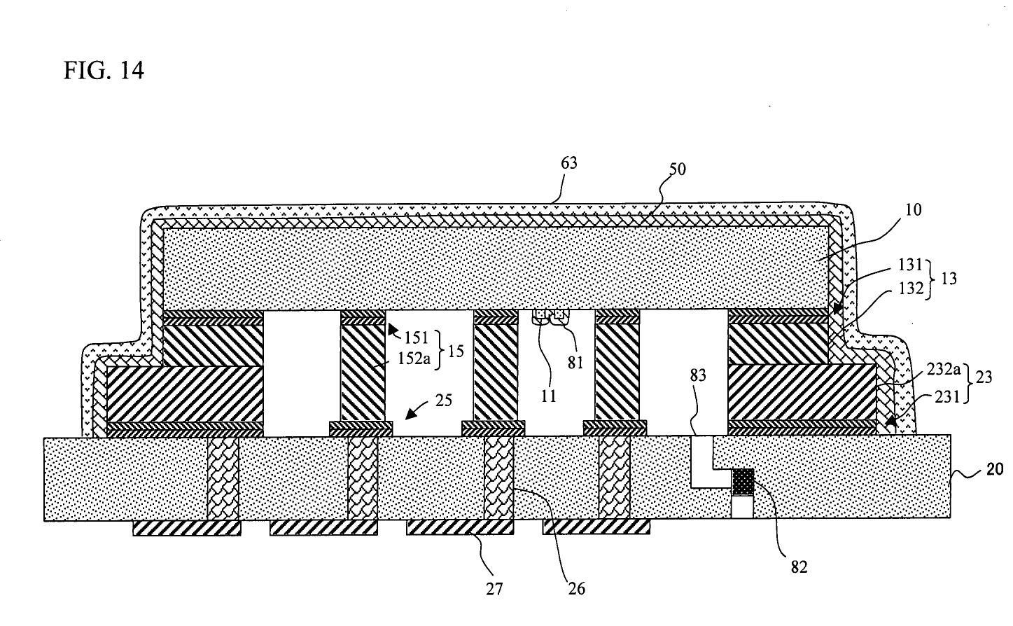

FIG. 14 is a section view of a acoustic wave device in accordance with a tenth embodiment of the present invention. In FIG. 14, the same components as those of the foregoing embodiments are denoted by the same reference numerals as the corresponding ones of the foregoing embodiments. The structure of this embodiment is the same as the structure of the first embodiment shown in FIG. 1, except for a through hole 83 for frequency adjustment. An insulating material such as a silicon oxide film is grown on comb-like electrodes, so as to adjust the center frequency of the pass band. The through hole 83 that penetrates the hermetically sealed inner space is used for the frequency adjustment. A silicon oxide film 81 is grown on the comb-like electrode 11 via the through hole 83 by a CVD technique. The growth of the silicon oxide film 81 is carried out only if necessary. After the process shown in FIG. 8C, the piezoelectric substrate 10 is diced to produce chips, and the frequency characteristics are measured. Based on the measurement results, whether the silicon oxide film 81 is to be grown is determined. After the silicon oxide film 81 is grown, a sealing material 82 such as a solder is inserted into the through hole 83 from the bottom surface of the supporting substrate 20. Thus, the through hole 83 is blocked by the sealing material 82. If the through hole 83 is bent as shown in FIG. 14, it is easy to insert the sealing material 82 into the through hole 83.

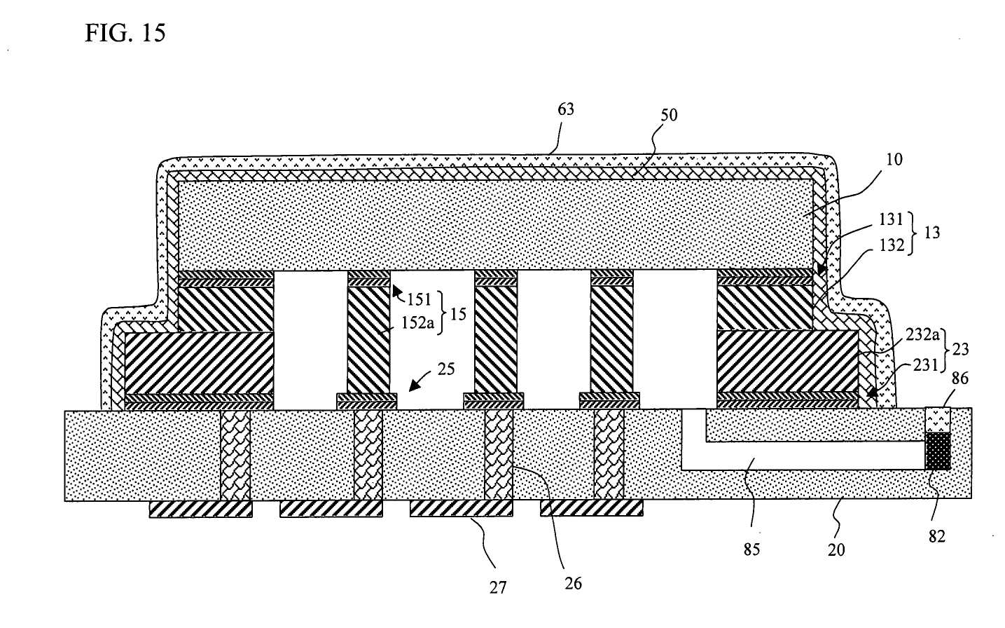

As shown in FIG. 15, the sealing material 82 may be inserted into a hole 85 from the circuit forming surface of the supporting substrate 20. The hole 85 having the sealing material 82 inserted therein is filled simultaneously when the coating film 63 is formed. The coating material located on the sealing material 82 is denoted by reference numeral 86.

The above described structure for frequency adjustment may be applied not only to the present embodiment but also to the other embodiments.

### Eleventh Embodiment

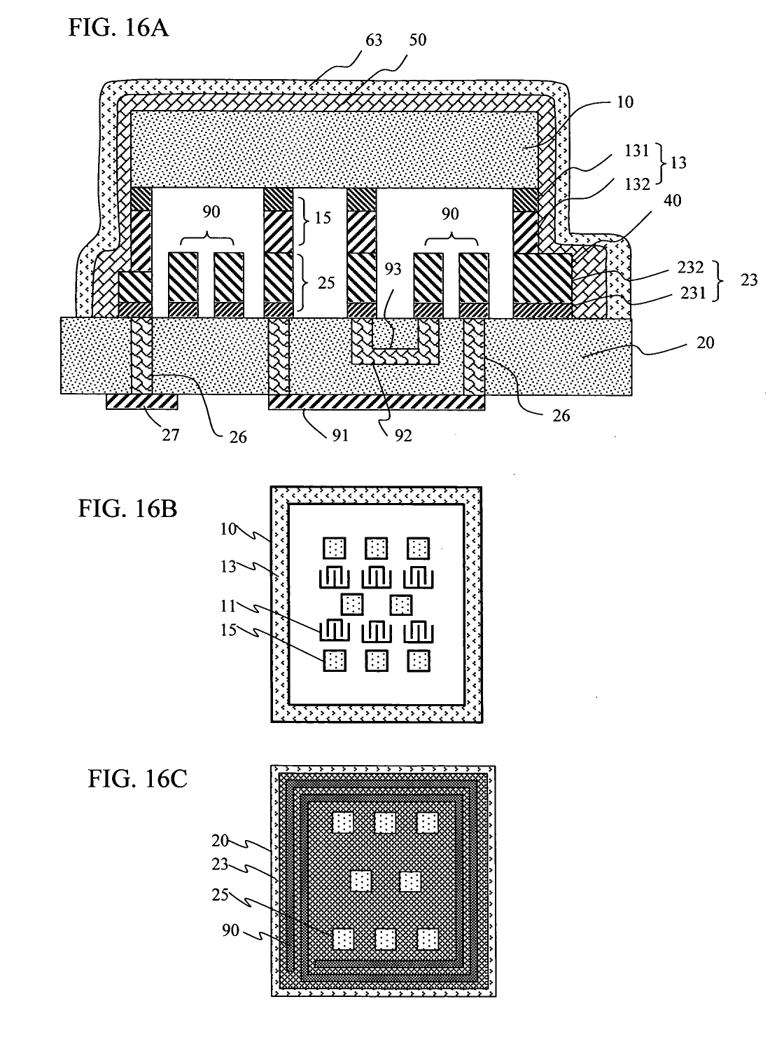

FIGS. 16A through 16C illustrate a acoustic wave device in accordance with an eleventh embodiment of the present invention. In FIGS. 16A through 16C, the same components as those of the foregoing embodiments are denoted by the same reference numerals as the corresponding ones of the foregoing embodiments. The acoustic wave filter of this embodiment is a duplexer. A duplexer is a filter having two pass bands that are close to each other. One of the pass bands is used for transmission, and the other one of the pass bands is used for reception. Two filters to provide the two pass bands are formed in terms of the circuit structure, and the two filters are connected to a common terminal to which antennas and other components are connected. A low pass filter for impedance matching is normally provided between the common terminal and the high-frequency filter. In the structure shown in FIGS. 16A through 16C, the inductor that constitutes the low pass filter is formed by a spiral wiring pattern 90.

The wiring pattern 90 that forms the inductor is located on the circuit forming surface of the supporting substrate 20, and surrounds the pads. The wiring pattern 90 contains a metal material formed on the adhesion layers, such as aluminum. In the example structure shown in FIGS. 16A through 16C, one end of the wiring pattern 90 is connected through a wiring route including a wire 91 formed on the bottom surface (the mounting surface) of the supporting substrate 20, and the other end of the wiring pattern 90 is connected (to the high-frequency filter, for example) through a wiring route including an inner pattern 92 formed in the supporting substrate 20. The wiring pattern 90 formed on the supporting substrate 20 made of ceramics faces the piezoelectric substrate 10 with an air gap in between. Accordingly, the Q value of the inductor can be made large.

The hermetical sealing in the structure shown in FIG. 16 is the same as in the first embodiment (the sealing material is not shown in FIG. 16A), but may also be applied to any other foregoing embodiment.

### Twelfth Embodiment

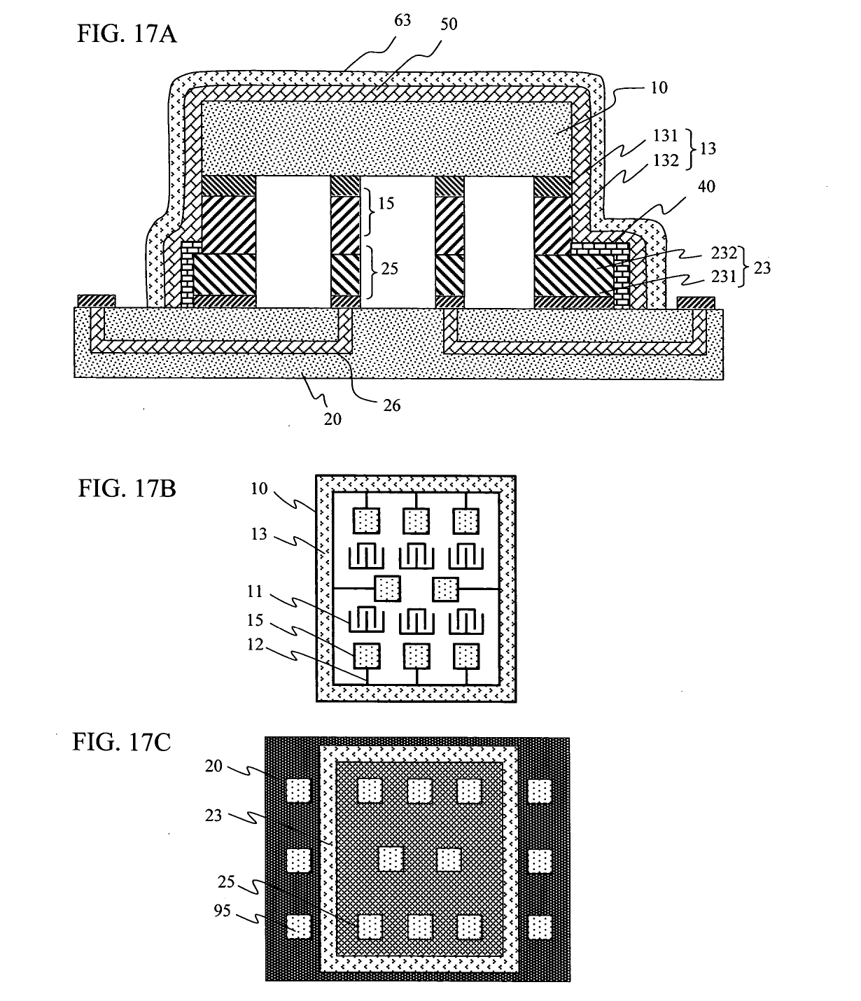

FIGS. 17A through 17C illustrate a acoustic wave device in accordance with a twelfth embodiment of the present invention. In FIGS. 17A through 17C, the same components as those of the foregoing embodiments are denoted by the same reference numerals as the corresponding ones of the foregoing embodiments. This embodiment is a modification of the first embodiment. While the external connection terminals 27 are formed on the bottom surface of the supporting substrate 20 in the first embodiment shown in FIGS. 1A through 1C, external connection terminals 95 are formed on the circuit forming surface of the supporting substrate 20 in the structure shown in FIGS. 17A through 17C. The terminals 25 connected to the comb-like electrodes 11 are connected to the terminals 95 via the inner wiring patterns 26 formed in the supporting substrate 20. The structure having the terminals 95 may also be applied to any other foregoing embodiment. With the terminals 95 as well as the terminals 27, the supporting substrate 20 can be externally connected from both surfaces.

### Thirteenth Embodiment

An eleventh embodiment of the present invention provides a method of forming a solder on a substrate, instead of a printing technique. By the method in accordance with the eleventh embodiment, finer patterns can be formed. The metal layer 23 and the terminals 25 on the supporting substrate 20 are made of copper. The copper layers are formed as follows. As an adhesion providing compound solution, a solution of 2 mass % of imidazole compound containing C₁₁H₂₃ as a R12 alkyl group and R11 hydrogen atoms is adjusted to have a pH of approximately 4 with acetic acid. This solution is then heated to 40° C. The substrate that has been subjected to preprocessing using a hydrochloric acid solution is soaked in the heated solution for three minutes, so that an adhesive material is formed on the copper circuit surface.

The substrate is then washed with water and dried. As a result, the adhesive material is deposited only on the copper circuit surface. After the drying, 89Sn/8Zn/3Bi solder particles of approximately 15 μm in mean particle size are sprinkled and lightly brushed, so that the solder particles selectively adhere to the adhesive material portions. The solder particles are then melted in an oven at 240° C. As a result, a eutectic solder thin layer of approximately 20 μm in thickness can be precisely formed on the exposed portion of the copper circuit. Surface mounting is then performed with an adhesive flux. The adhesive flux is produced by adding hydrogenated caster oil as a thixotropic agent to polymerized rosin and disproportioned rosin, with propylene glycol monophenyl ether being a solvent. This flux is printed to have a thickness of 100 μm, and a piezoelectric substrate is mounted on the flux. The piezoelectric substrate is then soldered by heating with a reflow heat source. Here, the reflowing conditions are a preheating temperature of 150° C., a preheating time of 60 seconds, and a reflow peak temperature of 230° C.

Surface mounting is then performed with an adhesive flux. The adhesive flux is produced by adding hydrogenated caster oil as a thixotropic agent to polymerized rosin and disproportioned rosin, with propylene glycol monophenyl ether being a solvent. This flux is printed to have a thickness of 100 μm, and bare chips (gold stud bumps of approximately 100 μm in height) are mounted onto the flux. The bare chips are then soldered by heating with a reflow heat source. Here, the reflowing conditions are a preheating temperature of 150° C., a preheating time of 60 seconds, and a reflow peak temperature of 230° C.

As described above, a reaction is caused in an adhesive providing compound so as to give adhesion after the bonding of a piezoelectric substrate to a supporting substrate. Solder particles then selectively adhere to the copper portions, and are reflowed to melt the solder. Thus, high reliability can be achieved in bonding.

As described above, the adhesion giving compound reacts so as to give adhesion after the piezoelectric substrate and the substrate are joined to each other. Solder particles then selectively adhere to the copper portions, and the solder is melted by reflowing. Thus, high reliability in bonding can be achieved.

### Fourteenth Embodiment

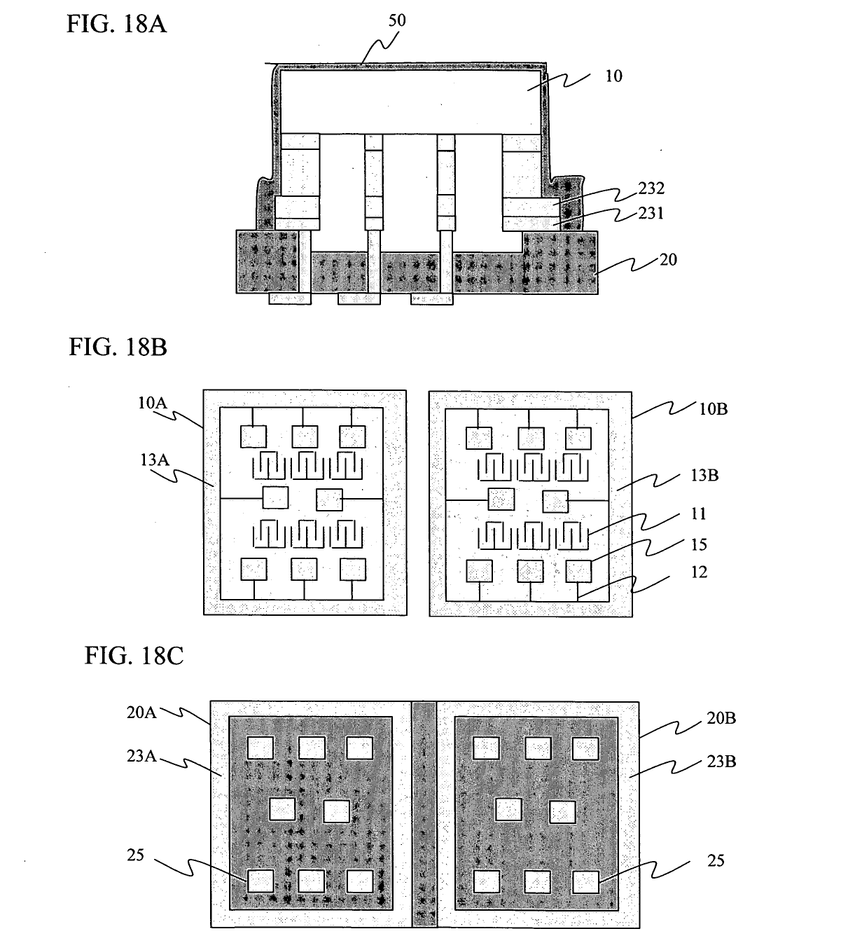

FIGS. 18A, 18B and 18C show an acoustic wave device according to a fourteenth embodiment of the present invention. A duplexer or a multi-band filter, which may be employed in a cellular phone, uses different types of acoustic wave filters such as SAW filters. The different types of SAW filters may be formed on a single piezoelectric substrate. In case where some SAW filters interface with each other, it is preferable to use separate piezoelectric substrates on which SAW filters are formed separately. FIG. 18B shows two piezoelectric substrates 10A and 10B on which separate SAW filters are formed. A single supporting substrate 20A is used to flip-chip bond the piezoelectric substrates 10A and 10B, which are separately provided with first metal films 13A and 13B. Similarly, the single supporting substrate 20A is provided with separate metal seal rings 23. Thus, the SAW filter chips 10A and 10B can be separately grounded, so that the filter characteristics can be prevented from being degraded.

### Fifteenth Embodiment

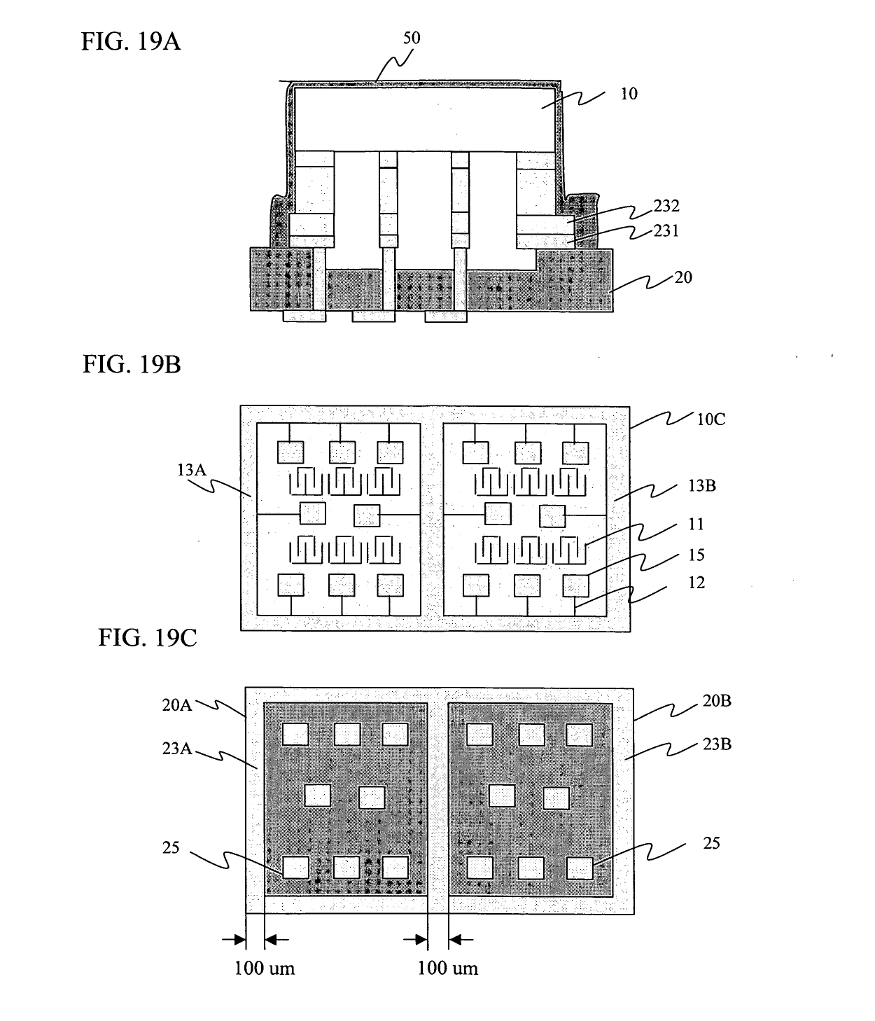

FIGS. 19A, 19B and 19C show an acoustic wave filter according to a fifteenth embodiment, in which a single piezoelectric substrate 10C is employed. The separate first seal rings 13A and 13B are provided on the single piezoelectric substrate 10C so that the corresponding side portions of the seal rings 13A and 13B overlap with each other to form an integrated intermediate portion. When the seal rings 13A and 13B are 100 μm wide, the piezoelectric substrate 10C can be longitudinally downsized by 100 μm if the intermediate portion is 100 μm wide. Thus, the integration density can be improved.

### Sixteenth Embodiment

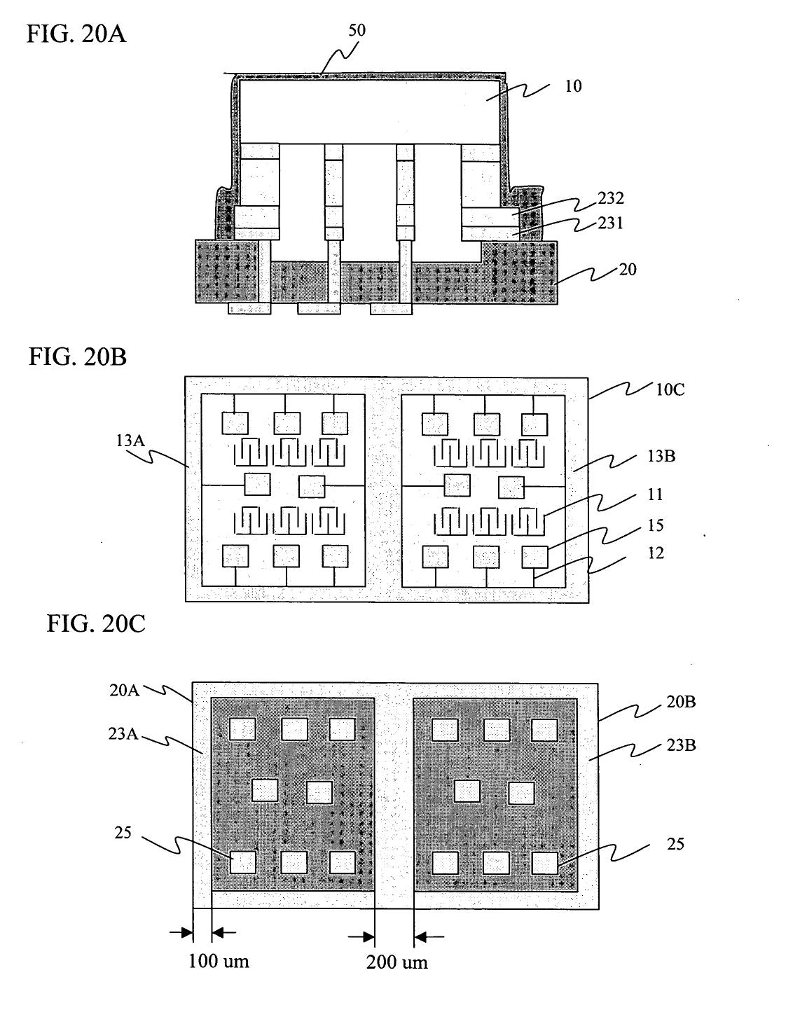

FIGS. 20A, 20B and 20C show an acoustic wave device according to a sixteenth embodiment of the present invention. The seal rings 13A and 13B are arranged so that the integrated intermediate portion has a width of 200 μm to ensure a process margin. The integrated intermediate portion may be wider to ensure a more process margin.

Although a few preferred embodiments of the present invention have been shown and described, it would be appreciated by those skilled in the art that changes may be made in these embodiments without departing from the principles and spirit of the invention, the scope of which is defined in the claims and their equivalents.

The present application is based on Japanese Patent Application Nos. 2003-385750 and 2004-186639 respectively filed on Nov. 14, 2003 and Jun. 24, 2004, and the entire disclosure of which is hereby incorporated by reference.

1. An acoustic wave device comprising:
a device substrate on which electrodes, first terminals, and a first metal seal layer located along an outer periphery are formed;
a supporting substrate on which second terminals to be connected to the first terminals, and a second metal seal layer to be joined to the first metal seal layer are formed; and
a conductive seal film provided on an outer surface of the device substrate, an outer surface of the first metal seal layer, and an outer surface of the second metal seal layer,
the electrodes and the first and second terminals being hermetically sealed with the first and second metal seal layers and the seal film.

2. The acoustic wave device as claimed in claim 1, further comprising an underlying metal layer provided on the device substrate, wherein the first terminals and the first metal seal layer are provided on the underlying metal layer.

3. The acoustic wave device as claimed in claim 1, wherein:
either ones of the first and second terminals have gold bumps, and the other terminals have a gold thin-film layer; and
either one of the first and second metal seal layers has a solder layer and the other has a gold layer.

4. The acoustic wave device as claimed in claim 1, wherein:
either ones of the first and second terminals have a solder layer and the other terminals have a metal layer; and
either one of the first and second metal seal layers has a solder layer and the other has a metal layer.

5. The acoustic wave device as claimed in claim 1, wherein:
either ones of the first and second terminals have a gold bump and the other terminals have a gold thin-film layer; and
either one of the first and second metal seal layers has a gold bump and the other has a metal layer.

6. The acoustic wave device as claimed in claim 1, wherein:
either ones of the first and second terminals have a gold plating layer, and the other have a metal layer; and
either one of the first and second seal layers has a gold plating layer and the other has a metal layer.

7. The acoustic wave device as claimed in claim 3, wherein the solder layer comprises an alloy layer containing silver and tin, a tin-antimony alloy layer, a gold-tin alloy layer, a gold-silicon alloy layer, a gold-germanium ally layer, or a tin-lead alloy layer.

8. The acoustic wave device as claimed in claim 2, wherein the underlying metal layer is partially covered with a cover film of a material that does not chemically react with the second metal seal layer.

9. The acoustic wave device as claimed in claim 8, wherein the cover film comprises one of a silicon oxide film and a silicon nitride film.

10. The acoustic wave device as claimed in claim 2, wherein:
the underlying metal layer comprises one of titanium, chromium, a titanium-tungsten alloy, copper, nickel, cobalt-nickel alloy, tungsten, and platinum; and the acoustic wave device further comprises a silicon oxide film on which the underlying metal layer is provided.

11. The acoustic wave device as claimed in claim 11, wherein the conductive seal film comprises an electrically conductive resin.

12. The acoustic wave device as claimed in claim 1, further comprising, on the device substrate, a first acoustic wave filter for transmitting, a second acoustic wave filter for receiving, and reactance or capacitance elements for phase adjusting.

13. The acoustic wave device as claimed in claim 1, wherein at least one of the first and second metal seal layers comprises a plurality of belt-like metal seal layers.

14. An acoustic wave device comprising:
a device substrate on which electrodes, first terminals, and a first metal seal layer located along an outer periphery are formed; and
a supporting substrate on which second terminals to be connected to the first terminals, and a second metal seal layer to be joined to the first metal seal layer are formed,
the electrodes and the first and second terminals being hermetically sealed with the first and second metal seal layers,
the supporting substrate having grooves inside or on its backside so as to form strips.

15. An acoustic wave device comprising:
a device substrate on which electrodes, first terminals, and a first metal seal layer located along an outer periphery are formed; and
a supporting substrate on which second terminals to be connected to the first terminals, and a second metal seal layer to be joined to the first metal seal layer are formed,
the electrodes and the first and second terminals being hermetically sealed with the first and second metal seal layers,
the supporting substrate having materials buried therein, the materials being arranged so as to form stripes and having a linear expansion coefficient different from that of the supporting substrate.

16. The acoustic wave device as claimed in any of claims 1, 14 and 15, wherein at least one of the first and second metal seal layers comprises two metals having different compositions.

17. The acoustic wave device as claimed in any of claims 1, 14 and 15, further comprising another seal film that covers the outer surfaces of the first and second metal seal layers and joining regions of the first and second metal seal layers, wherein the conductive seal film is provided outside of said another seal film.

18. The acoustic wave device as claimed in claim 17, wherein said another seal film comprises solder, adhesive or indium.

19. The acoustic wave device as claimed in any of claims 1, 14 and 15, further comprising a second supporting substrate made of a material different from that of which the device substrate is made, wherein the second supporting substrate is joined to a surface of the device substrate opposite to another surface thereof on which the electrodes, the first terminals, and the first metal seal layer are provided.

20. The acoustic wave device as claimed in any of claims 1, 14 and 15, further comprising a second supporting substrate made of a material different from that of which the device substrate is made, wherein the second supporting substrate having first and second surfaces is joined to the device substrate so that the first surface of the second supporting substrate faces a surface of the device substrate opposite to another surface thereof on which the electrodes, the first terminals, and the first metal seal layer are provided, a passive element being provided on the second surface of the second supporting substrate opposite to the first surface.

21. The acoustic wave device as claimed in any of claims 1, 14 and 15, further comprising a second supporting substrate made of a material different from that of which the device substrate is made, wherein the second supporting substrate having first and second surfaces is joined to the device substrate so that the first surface of the second supporting substrate faces a surface of the device substrate opposite to another surface thereof on which the electrodes, the first terminals, and the first metal seal layer are provided, another acoustic wave device pattern being formed on said another surface of the device substrate.

22. The acoustic wave device as claimed in any of claims 1, 15 and 16, wherein the device substrate has a hole extending inwards from the surface thereof, and a member that fills the hole.

23. The acoustic wave device as claimed in any of claims 1, 14 and 15, further comprising a pattern that is provided on a surface of the device substrate and is located further in than the second metal seal layer, wherein the pattern forms an inductor.

24. The acoustic wave device as claimed in claim 1, wherein the conductive seal film is connected to ground.

25. The acoustic wave device as claimed in claim 1, wherein:
the device substrate comprises first and second chips on which patterns for acoustic wave devices are separately formed; and
the first metal seal layer comprises first and second seal layers respectively and separately provided on the first and second chips.

26. The acoustic wave device as claimed in claim 1, wherein:
the device substrate is a single chip on which patterns for acoustic wave devices are separately formed; and
the first metal seal layer comprises first and second seal layers respectively provided for the acoustic wave devices so that the first and second seal layers of the first metal seal layer have a common portion having a width equal to that of another portion of each of the first and second seal layers.

27. The acoustic wave device as claimed in claim 1, wherein:
the device substrate is a single chip on which patterns for acoustic wave devices are separately formed; and
the first metal seal layer comprises first and second seal layers respectively provided for the acoustic wave devices so that the first and second seal layers of the first metal seal layer have a common portion having a width that is greater than that of another portion of each of the first and second seal layers and is less than twice the width of said another portion of each of the first and second seal layers.

28. The acoustic wave device as claimed in any of claims 1, 14 and 15, wherein the metal seal layer or the solder layer has a flattened surface.
